(19) United States
(12) Patent Application Publication
(10) Pub. No.: US 2015/0145386 A1
(43) Pub. Date: May 28, 2015

(54) HOUSING FOR AN ELECTRONIC DEVICE

(71) Applicant: HON HAI PRECISION INDUSTRY CO., LTD., New Taipei (TW)

(72) Inventor: SHAO-HAN CHANG, New Taipei (TW)

(21) Appl. No.: 14/496,632

(22) Filed: Sep. 25, 2014

(30) Foreign Application Priority Data
Nov. 22, 2013 (CN) 2013105928587

(51) Int. Cl. H05K 5/06; H05K 5/00

(52) U.S. Cl. CPC H05K 5/06; H05K 5/0086
USPC 312/223.1

(57) ABSTRACT

A housing for an electronic device includes a first member, a second member, a first glue layer, and a second glue layer. The first member includes a cover plate with a continuous protrusion along the periphery of the cover plate and extending away from the cover plate. The second member includes a flat bottom plate with a continuous side wall along the periphery of the bottom plate and extending away from the bottom plate. The side wall define a continuous groove, and the protrusion of the first member is fittable within the continuous groove of the second member and attached to the second member by one or more of the first glue layer and the second glue layer.

### FIELD

The subject matter herein generally relates to a housing for an electronic device, and more particularly to a waterproof housing that has good applicability.

### BACKGROUND

Recent mobile terminal devices are required to be waterproof in addition to being small and having a high strength.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of an embodiment of a waterproof housing.

FIG. 2 is an exploded isometric view of the waterproof housing of FIG. 1.

FIG. 3 is an isometric view of a first member of the waterproof housing.

FIG. 4 is a cross-sectional view of FIG. 1 taken along line IV-IV.

FIG. 5 is a cross-sectional view of FIG. 1 taken along line V-V.

FIG. 6 is an enlarged view of circled portion VI of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

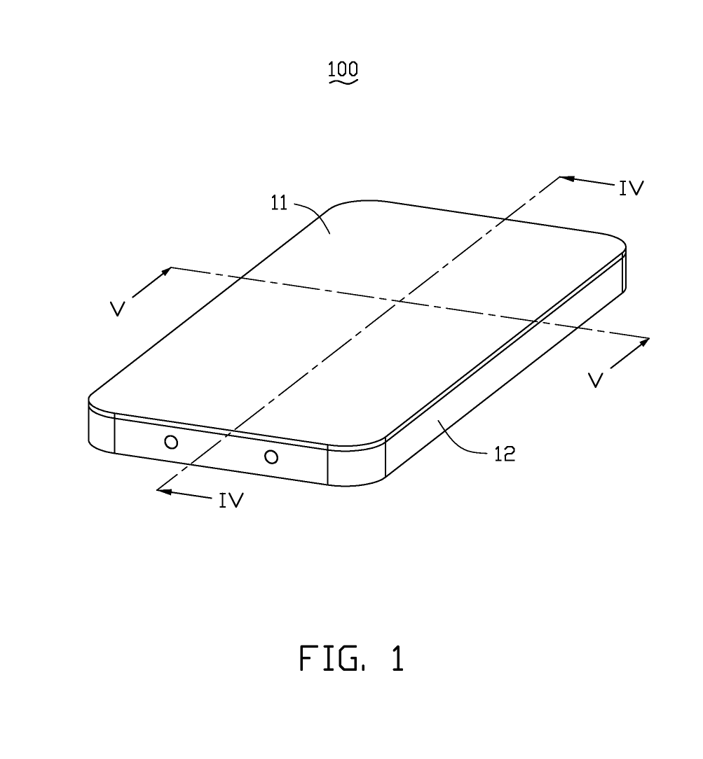

FIG. 1 illustrates that a housing 100 for an electronic device can include a first member 11 and a second member 12. The first member 11 can be assembled to the second member 12 to form the housing 100.

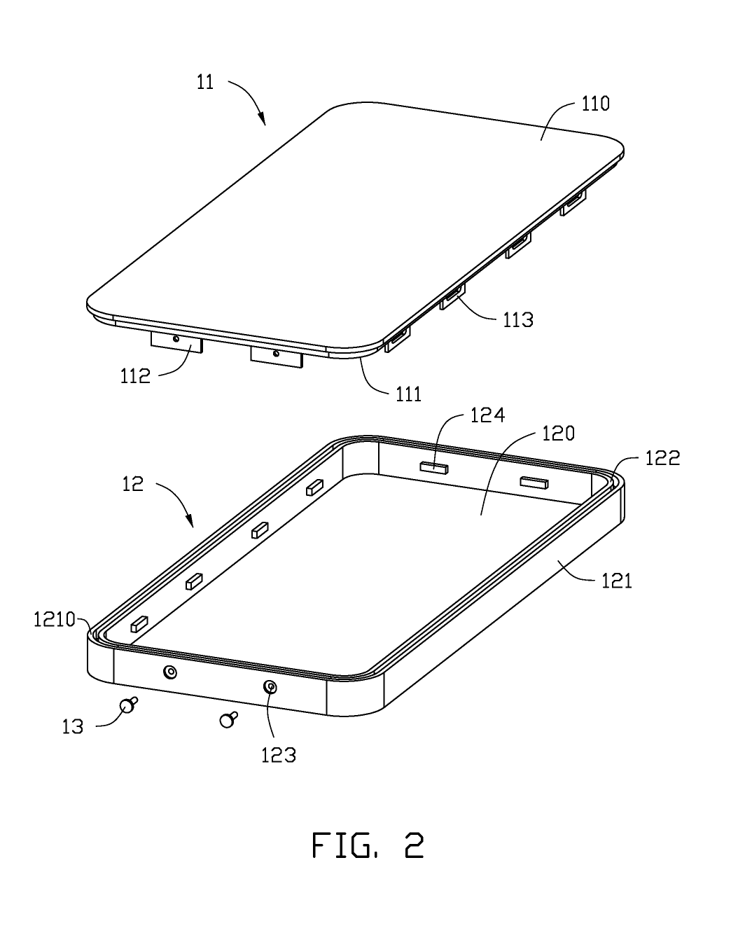

FIG. 2 illustrates that the first member 11 can be a substantially rectangular plate. The first member 11 can include a substantially flat cover plate 110 with a continuous protrusion 111 along the periphery of the cover plate 110 and extending away from the cover plate 110. In at least one embodiment, the first member 11 can further include two screw portions 112 and a plurality of latching portions 113 extending substantially perpendicularly from the cover plate 110. The screw portion 112 and the latching portions 113 can be substantially rectangular.

The second member 12 can include a substantially flat bottom plate 120 with a continuous side wall 121 along the periphery of the bottom plate 120 and extending away from the bottom plate 120. The bottom plate 120 and the side wall 121 form a box-shaped structure. The continuous side wall 121 has a top surface 1210 positioned furthest from the bottom plate 120, and the top surface 1210 can have a continuous groove 122 extending down into the side wall 121 towards the bottom plate 120. The protrusion 111 of the first member 11 is fittable within the continuous groove 122 of the second member 12 and attached to the second member 12. In at least one embodiment, the second member 12 can further define two threaded holes 123 through the side wall 121, and a plurality of holding portions 124 can extend from inner surfaces of the other three side wall 121. The threaded holes 123 can correspond to the screw portions 112, and the holding portions 124 can correspond to the latching portions 113.

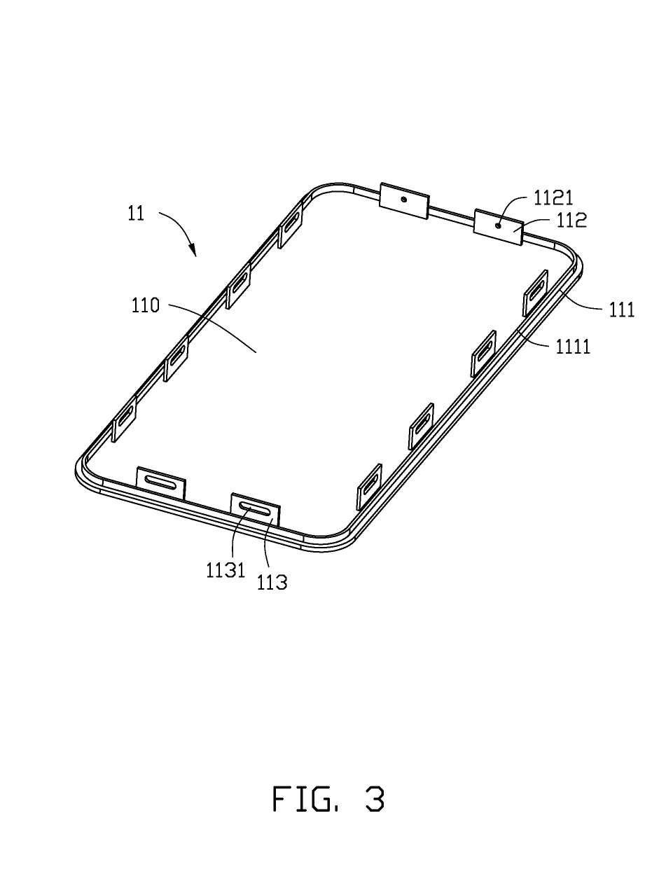

FIG. 3 illustrates that the continuous protrusion 111 can be substantially perpendicular to the cover plate 110. The continuous protrusion 111 can include an end surface 1111 away from the cover plate 110. The end surface 1111 can be substantially parallel to the cover plate 110.

Each screw portion 112 can define a through hole 1121, and each latching portion 113 can define a latching hole 1131. The latching holes 1131 can have a shape substantially identical to a shape of the holding portions 124, and each holding portion 124 can insert through the corresponding latching hole 1131. Referring to FIG. 2 and FIG. 3, the waterproof housing 100 can further include two fastening members 13, which can be threaded through the threaded holes 123 and the through holes 1121 screw portion.

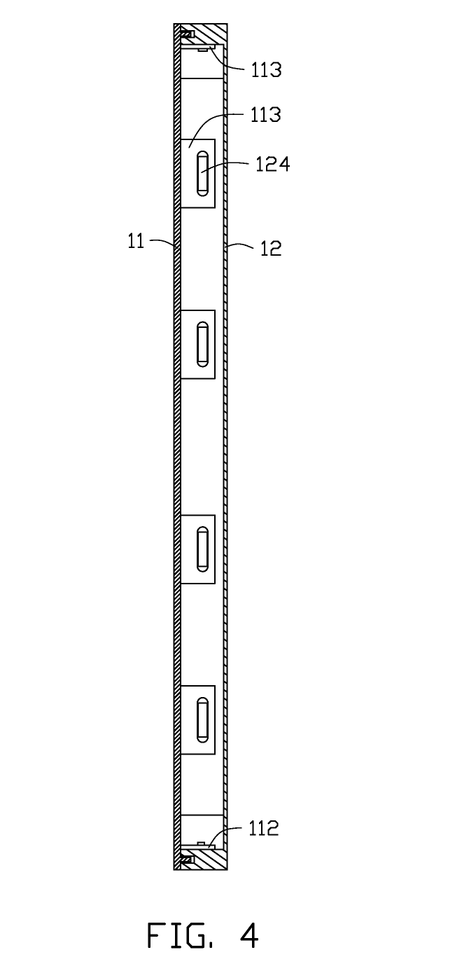

FIG. 4 illustrates that the first member 11 and the second member 12 can be assembled together. Each holding portion 124 can be latched in the corresponding latching portion 113.

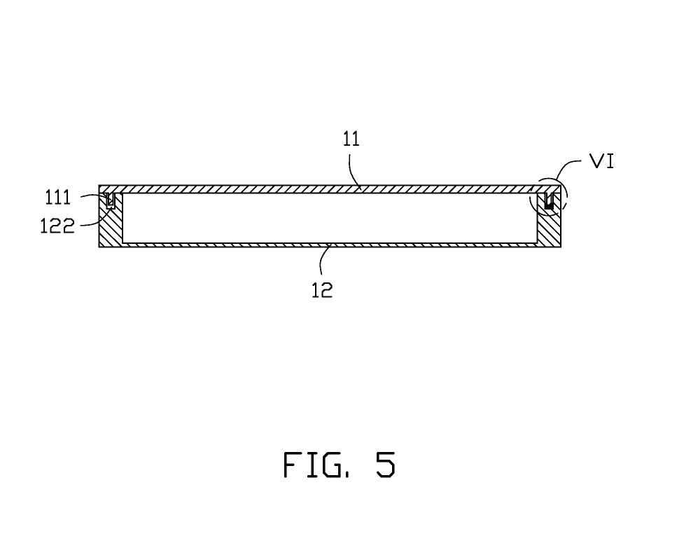

FIG. 5 illustrates that the first member 11 can be engaged with the second member 12. The continuous protrusion 111 can be received in the continuous groove 122. A width and a height of the continuous groove 122 can be larger than a width and a height of the continuous protrusion 111, to easily latch the continuous protrusion 111 in the continuous groove 122.

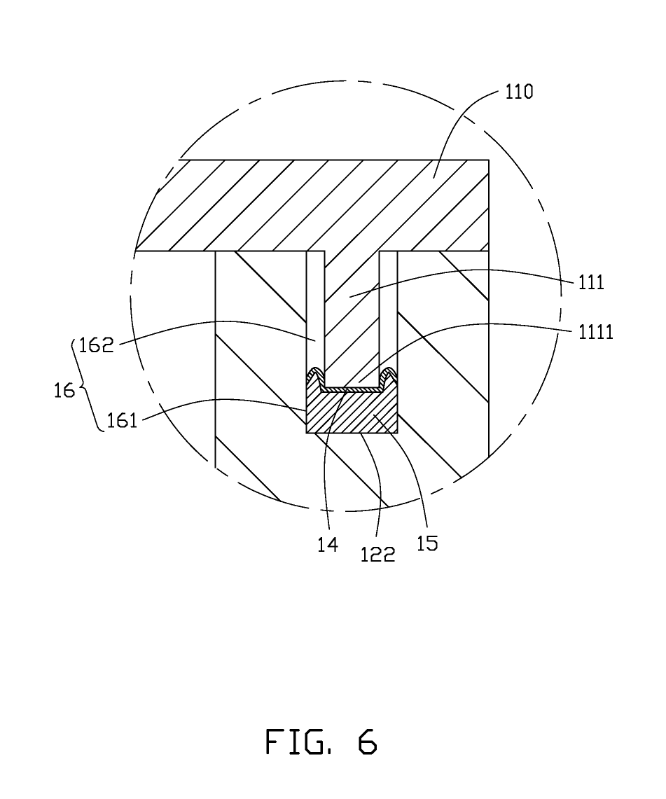

FIG. 6 illustrates that the continuous protrusion 111 can cooperatively define a fit clearance 16 with the continuous groove 122. The fit clearance 16 can include a first clearance 161 parallel to the cover plate 110, and a second clearance 162 perpendicular to the cover plate 110.

The housing 100 can further include a first glue layer and a second glue layer in the continuous groove 122 to make the housing 100 waterproof. The protrusion 111 of the first member 11 is fittable within the continuous groove 112 of the second member 12 and attached to the second member 12 by one or more of the first glue layer and the second glue layer. The first glue layer can be a solidified glue layer 14, and the second glue layer can be a flexible glue layer 15. The solidified glue layer 14 can be located on top of the flexible glue layer 15. The solidified glue layer 14 and the flexible glue layer 15 can fill in the first clearance 161. A thickness of the solidified glue layer 14 can be smaller than a thickness of the flexible glue layer 15. The solidified glue layer 14 and the flexible glue layer 15 can fill in a portion of the second clearance 162 as the continuous protrusion 111 is inserted into the continuous groove 122. Thus, a good sealing performance and a good dust-and-water-proof performance can be realized.

A method for making the solidified glue layer 14 and the flexible glue layer 15 is described as follows. Firstly, a prepared glue layer can be formed at the bottom of the continuous groove 122 by a precision dispensing machine (not shown). Then, the prepared glue layer can be cured by ultraviolet (UV) light to form the solidified glue layer 14, which is fully solidified, and the flexible glue layer 15, which is not solidified or not fully solidified.

In assembly, the continuous protrusion 111 can be inserted into the continuous groove 122, and the end surface 1111 of the continuous protrusion 111 can contact the solidified glue layer 14. The continuous protrusion 111 can cause the solidified glue layer 14 and the flexible glue layer 15 to fill in a portion of the second clearance 162, thereby enlarging a sealing volume of the solidified glue layer 14 and the flexible glue layer 15, and a good dust-and-water-proof performance can be realized. At the same time, the holding portions 124 can be latched in the corresponding latching members 113, and the fastening members 13 can be threaded into the threaded holes 123 and the screw portions 112. Thus, the first member 11 and the second member 12 can be firmly assembled together.

In at least one embodiment, the continuous protrusion 111 can insert less than 1 millimeter through the combined solidified glue layer 14 and flexible glue layer 15.

In other embodiments, the screw portion 112 and the latching portions 113 can be omitted, as long as the first member 11 and the second member 12 can be assembled together by other methods.

In other embodiments, a number of the screw portions 112 can be more than two, and a number of the latching members 113 can be changed according to a size of the first member 11.

As the continuous protrusion 111 can be easily latched in the continuous groove 122, there is no need to apply much force to assemble the first member 11 to the second member 12. Thus, assembling the first member 11 to the second member 12 is easy, and the waterproof housing 100 is prevented from being damaged. Furthermore, the solidified glue layer 14 and the flexible glue layer 15 can realize a good dust-and-water-proof performance of the waterproof housing 100.

The embodiments shown and described above are only examples. Many details are often found in the art such as the other features of a waterproof housing. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A housing for an electronic device, the housing comprising:
a first member having a substantially flat cover plate with a continuous protrusion along the periphery of the cover plate and extending away from the cover plate;
a second member having a substantially flat bottom plate with a continuous side wall along the periphery of the bottom plate and extending away from the bottom plate;
a first glue layer; and
a second glue layer;
wherein, the continuous side wall has a top surface positioned furthest from the bottom plate, the continuous side wall top surface having a continuous groove extending down into the side wall towards the bottom plate;
wherein, the first glue layer and the second glue layer are positioned within the continuous groove of the side wall; and
wherein, the protrusion of the first member is fittable within the continuous groove of the second member and attached to the second member by one or more of the first glue layer and the second glue layer.

2. The housing of claim 1, wherein a width and a height of the continuous groove are larger than a width and a height of the continuous protrusion.

3. The housing of claim 1, wherein the continuous protrusion and the continuous groove cooperatively form a fit clearance; the fit clearance comprises a first clearance parallel to the cover plate and a second clearance perpendicular to the cover plate.

4. The housing of claim 3, wherein the first glue layer and the second glue layer fill in the first clearance.

5. The housing of claim 4, wherein the first glue layer and the second glue layer fill in a part of the second clearance when the continuous protrusion inserted into the continuous groove.

6. The housing of claim 1, wherein the first glue layer is located on top of the second glue layer.

7. The housing of claim 1, wherein the first glue layer and the second glue layer are made of a glue layer under ultraviolet curing; the first glue layer is a solidified glue layer, and the second glue layer is a flexible layer.

8. The housing of claim 1, wherein the continuous protrusion is substantially perpendicular to the cover plate.

9. The housing of claim 1, wherein the first member further comprises at least one screw portion with a through hole near the continuous protrusion, and the second member further comprises at least one threaded hole corresponding to the through hole.

10. The housing of claim 1, wherein;
the first member further comprises at least one latching portion with a latching hole near the continuous protrusion, and the second member further comprises at least one holding portion corresponding to the latching portion;
the holding portion is formed on the inner surface of the side wall and latched in the latching hole.
